(19) United States
(12) Patent Application Publication
(10) Pub. No.: US 2026/0042186 A1
(43) Pub. Date: Feb. 12, 2026

(54) ONE-SIDE POLISHING APPARATUS FOR WORKPIECE, METHOD FOR ONE-SIDE POLISHING OF WORKPIECE, AND METHOD FOR MANUFACTURING SILICON WAFERS

(71) Applicant: SUMCO CORPORATION, Tokyo (JP)

(72) Inventors: Yuki NAKANO, Tokyo (JP); Takayuki KIHARA, Tokyo (JP); Takeshi TAKAHASHI, Tokyo (JP)

(73) Assignee: SUMCO CORPORATION, Tokyo (JP)

(21) Appl. No.: 19/124,951

(22) PCT Filed: Jun. 26, 2023
(86) PCT No.: PCT/JP2023/023546

§ 371 Date: Apr. 28, 2025

(30) Foreign Application Priority Data
Nov. 28, 2022 (JP) 2022-189485

(51) Int. Cl. B24B 55/06; B24B 37/04; B24B 37/12; B24B 53/017; B24B 57/02

(52) U.S. Cl. CPC B24B 55/06; B24B 37/042; B24B 37/12; B24B 53/017; B24B 57/02

(57) ABSTRACT

The one-side polishing apparatus for a workpiece of the present disclosure further comprises a surface displacement measurement section that can measure displacement of an exposed top surface, which is a top surface of the polishing pad that is not covered by the polishing head. The method for one-side polishing of a workpiece of the present disclosure polishes, in the polishing process, one side of the workpiece while measuring displacement of the exposed upper surface by the surface displacement measurement section that can measure the displacement of the exposed upper surface. The method for manufacturing silicon wafers of the present disclosure uses the method for one-side polishing of a workpiece as described above.

### TECHNICAL FIELD

This disclosure relates to a one-side polishing apparatus for a workpiece, a method for one-side polishing of a workpiece, and a method for manufacturing silicon wafers.

### BACKGROUND

In the one-side polishing of a workpiece (e.g. a silicon wafer), a polishing plate and a polishing pad, which have a diameter larger than the wafer, are rotated while the polishing pad is pressed against the wafer to polish the wafer. At that time, the polishing plate and the polishing pad are rotating, therefore, the polishing pad is subjected to repeated pressure loading and unloading in relation to the pressing pressure from the wafer. In such polishing, it is known that the viscoelasticity of the polishing pad has an effect on the distribution of the amount of polishing, particularly on the outer circumferential portion of the wafer, and polishing pads with various physical properties (including viscoelasticity) have been proposed (see, for example, Patent Document 1).

### CITATION LIST

### Patent Literature

PTL 1: JP 2013-089767 A1
PTL 2: JP H11-165256 A1

### SUMMARY

### Technical Problem

However, only with the conventional method of determining the physical properties of the polishing pad, it was difficult to express the amount of displacement of the polishing pad during actual polishing. In response to this, Patent Document 2 proposes measuring the deformation of the polishing pad when the wafer is pressed against the same, however, it was not possible to measure the behavior of the polishing pad recovering its deformation after the wafer is pressed against the same. For this reason, a method capable of measuring the amount of dynamic displacement of the polishing pad during one-side polishing has been desired.

Therefore, the object of the present disclosure is to provide a one-side polishing apparatus for a workpiece, a method for one-side polishing of a workpiece, and a method for manufacturing silicon wafers, that can measure the amount of dynamic displacement of the polishing pad during one-side polishing.

### Solution to Problem

The gist of the present disclosure is as follows.

(1) A one-side polishing apparatus for a workpiece, comprising:
a polishing plate with a larger diameter than the workpiece;
a polishing pad attached to the polishing plate;
a polishing head that can hold the workpiece and press the same against the polishing pad; and
a polishing liquid supply nozzle that supplies polishing liquid to the polishing pad, wherein
the apparatus further comprises a surface displacement measurement section that can measure displacement of an exposed top surface, which is a top surface of the polishing pad that is not covered by the polishing head.

(2) The one-side polishing apparatus for a workpiece as described in (1) above, further comprising a polishing liquid removal section that removes the polishing liquid from the exposed top surface.

(3) The one-side polishing apparatus for a workpiece as described in (2) above, wherein the polishing liquid removal section is configured to be capable of blowing air onto the exposed top surface.

(4) The one-side polishing apparatus for a workpiece as described in any one of (1) to (3) above, wherein the surface displacement measurement section is arranged at a plurality of the locations.

(5) The one-side polishing apparatus for a workpiece as described in any one of (1) to (4) above, wherein the workpiece is a wafer.

(6) A method for one-side polishing of a workpiece, including: a polishing process for polishing one side of the workpiece, using a polishing plate with a larger diameter than the workpiece; a polishing pad attached to the polishing plate; a polishing head that can hold the workpiece and press the same against the polishing pad; and a polishing liquid supply nozzle that supplies polishing liquid to the polishing pad, and pressing the workpiece against the polishing pad while rotating the polishing plate and the polishing pad and supplying the polishing liquid from the polishing liquid supply nozzle to the polishing pad, wherein in the polishing process, one side of the workpiece is polished while measuring displacement of an exposed upper surface, which is a top surface of the polishing pad that is not covered by the polishing head, by a surface displacement measurement section that can measure the displacement of the exposed upper surface.

(7) The method for one-side polishing of a workpiece as described in (6) above, wherein one side of the workpiece is polished while removing the polishing liquid from the exposed top surface.

(8) The method for one-side polishing of a workpiece as described in (7) above, wherein in the polishing process, one side of the workpiece is polished while blowing air onto the exposed top surface to remove the polishing liquid.

(9) The method for one-side polishing of a workpiece as described in (6) or (7) above, further including a preliminary process for measuring displacement of the exposed top surface without pressing the workpiece against the polishing pad, wherein a dynamic change in displacement of the exposed top surface during one-side polishing of the workpiece is calculated by comparing a measurement result from the preliminary process with a result of measuring the displacement of the exposed top surface while pressing the workpiece against the polishing pad.

(10) The method for one-side polishing of a workpiece as described in any one of (6) to (9), wherein the workpiece is a wafer.

(11) A method for manufacturing silicon wafers using the method for one-side polishing of a workpiece as described in (10) above.

### Advantageous Effect

According to the present disclosure, it is possible to provide a one-side polishing apparatus for a workpiece, a method for one-side polishing of a workpiece, and a method for manufacturing silicon wafers, that can measure the amount of dynamic displacement of the polishing pad during one-side polishing.

### BRIEF DESCRIPTION OF THE DRAWINGS

In the accompanying drawings:

FIG. 1 is a schematic top view of a one-side polishing apparatus for a workpiece according to one embodiment of the present disclosure;

FIG. 2 is a schematic side view of the one-side polishing apparatus for a workpiece according to one embodiment of the present disclosure;

FIG. 3 is a graph that provides the relationship between measurement time and displacement of an exposed top surface;

FIG. 4 is a graph that provides data after outliers in FIG. 3 have been removed;

FIG. 5 is a graph that provides data for the time moving average, in which the time width (several times the rotation cycle) for the centered moving average for the data in FIG. 4 is changed;

FIG. 6 provides data in which the data in FIG. 4 are averaged by N;

FIG. 7 is a graph that provides data when a preliminary process has been performed in which displacement of the exposed top surface is measured in the same way without pressing the polishing pad against the wafer;

FIG. 8 is a graph that provides the relationship between measurement time and absolute amount of displacement on the exposed top surface; and

FIG. 9 is a graph that provides the case where air was not blown.

### DETAILED DESCRIPTION

Hereinafter, embodiments of the present disclosure will be described in detail with reference to the drawings.

### <One-Side Polishing Apparatus for Workpiece>

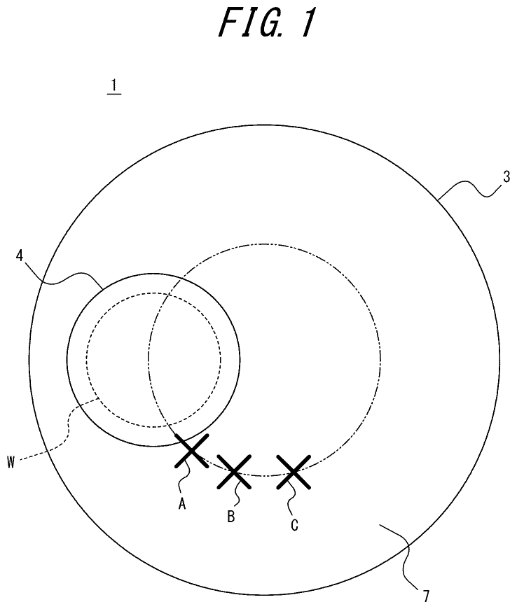

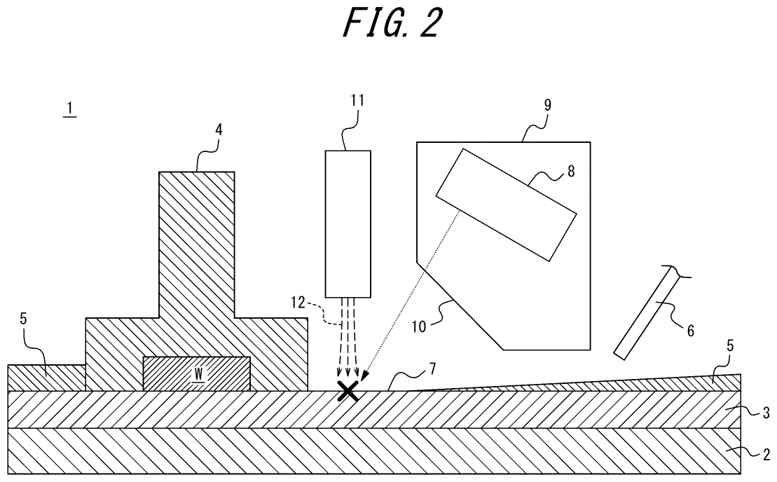

FIG. 1 is a schematic top view of a one-side polishing apparatus for a workpiece according to one embodiment of the present disclosure. FIG. 2 is a schematic side view of the one-side polishing apparatus for a workpiece according to one embodiment of the present disclosure.

As illustrated in FIGS. 1 and 2, this one-side polishing apparatus 1 comprises a polishing plate 2 with a larger diameter than a workpiece (e.g., a silicon wafer) W, a polishing pad 3 attached to a top surface of the polishing plate 2, a polishing head 4 that can hold the workpiece W and press the same against the polishing pad 3, and a polishing liquid supply nozzle 6 that supplies polishing liquid (polishing slurry) 5 to the polishing pad 3.

In the illustrated example, a top surface of the polishing pad 3 slides against one side (the bottom surface) of the workpiece W to polish the one side of the workpiece W. Although it is omitted in FIG. 2, the polishing head 4 may have a backing pad that serves as a holding section for a top surface of the workpiece W and a retainer ring (whose inner diameter is equal to or greater than diameter of the workpiece W) that serves as a holding section for the side surface of the same. The polishing liquid 5 contains at least a water-soluble polymer, and can also contain abrasive grains and an alkaline solution, and the water-soluble polymer can function as a protective agent for the workpiece W.

Also, although it is omitted from the illustration, the polishing head 4 can be provided with a shaft section that raises and lowers and rotates the polishing head 4, and a rotating frame section provided at the lower end of the shaft section and having the backing pad attached to the underside thereof. In addition, the one-side polishing apparatus 1 comprises a rotating mechanism (such as a shaft or motor) that is connected to the polishing plate 2 and rotates the polishing plate 2.

Here, as illustrated in FIGS. 1 and 2, the top surface of the polishing pad 3 is made up of a part covered by the polishing head 4 and a part not covered by the polishing head (hereinafter, referred to as an “exposed top surface 7”). Although there is the polishing liquid 5 on this exposed top surface 7 (the part not covered by the polishing head 4) of the polishing pad during polishing, this exposed top surface 7 is not being pressed by the polishing head 4 or other mechanisms. In addition, this one-side polishing apparatus 1 comprises a surface displacement measurement section 8 that can measure displacement of the exposed top surface 7. The surface displacement measurement section 8 can be a non-contact displacement meter such as a laser displacement meter, although there are no particular restrictions.

As illustrated in FIG. 2, the surface displacement measurement section 8 is surrounded by a waterproof container 9, which protects it from the splashing of polishing liquid 5. In this example, the waterproof container 9 is made of transparent acrylic. Also, in this example, the waterproof container 9 has a draining slope 10, which prevents the adhered polishing liquid 5 from remaining on the waterproof container 9.

Furthermore, as illustrated in FIG. 2, this one-side polishing apparatus 1 further comprises a polishing liquid removal section 11 that removes the polishing liquid 5 from the exposed top surface 7. The polishing liquid removal section 11 can be any mechanism that can remove the polishing liquid from the surface without exerting enough pressure on it to affect the displacement measurement of the polishing pad 3. In this example, the polishing liquid removal section 11 is an air blowing section that is configured to be capable of blowing air 12 onto the exposed top surface 7. This air blowing section is positioned above the measurement point, and by blowing air onto the polishing pad 3 from above, the polishing liquid 5 can be removed from the measurement point.

As illustrated in FIG. 1, it is preferable that the surface displacement measurement section 8 is arranged at a plurality of the locations. There are three surface displacement measurement sections 8 arranged in correspondence with three measurement points A, B, and C in FIG. 1, but the number of the surface displacement measurement sections 8 is not limited to this example. In the illustrated example, the measurement point A is a measurement point immediately after the polishing pad 3 is released from the pressure generated between the polishing pad 3 and the workpiece W, and the measurement points B and C are points at which a specified amount of time has elapsed after the pressure is released, respectively. In this example, the measurement points A to C are arranged at equal intervals. On the other hand, the measurement points can be arranged in various ways that are suitable for observing the dynamic changes in displacement of the exposed top surface 7 of the polishing pad 3, and they do not necessarily have to be arranged at equal intervals. For example, the measurement points may be arranged at a position immediately after the polishing pad 3 is released from the pressure generated between the polishing pad 3 and the workpiece W, and at a position corresponding to the position where the shape of the polishing pad 3 has almost recovered.

The effects of the one-side polishing apparatus according to this embodiment will be described below.

The one-side polishing apparatus 1 for a workpiece W in this embodiment comprises the surface displacement measurement section 8 that can measure displacement of the exposed top surface 7. By continuously measuring the displacement of the exposed top surface 7 during one-side polishing of the workpiece W using the surface displacement measurement section 8, it is possible to understand the dynamic displacement behavior of the polishing pad, including the load and unloading of the pressing pressure from the workpiece W. By appropriately selecting the resolution of the surface displacement measurement section 8, for example, it is possible to grasp the temporal change in the displacement of the polishing pad 3 of several microns. As a result, it is possible to evaluate the variation in the physical properties of the polishing pad which could not be determined by measuring the displacement of the polishing pad (of several hundred microns) with the wafer pressed down.

As described above, the one-side polishing apparatus 1 for a workpiece W of this embodiment can measure the amount of dynamic displacement of the polishing pad during one-side polishing.

Here, it is preferable for the one-side polishing apparatus 1 to further comprise a polishing liquid removal section 11 that removes the polishing liquid 5 from the exposed top surface 7. This is because it prevents the polishing liquid 5 from affecting the measurement, and allows the amount of dynamic displacement of the polishing pad 3 during one-side polishing to be measured with high accuracy. The polishing liquid removal section 11 is preferably configured to be capable of blowing air 12 onto the exposed top surface 7. This is because the simple structure makes it possible to avoid being affected by the polishing liquid 5.

In addition, it is preferable that the surface displacement measurement section 8 is arranged at a plurality of the locations. This is because it allows grasping the temporal change in displacement of the polishing pad 3 within one cycle, including the load and unloading of the pressing pressure from the workpiece W. By having the plurality of locations arranged in the circumferential direction of the polishing pad 3, it is possible to grasp the temporal changes in the same location within the polishing pad 3, and thus the dynamic changes in the polishing pad 3 can be more accurately measured.

### <Method for One-Side Polishing of Workpiece>

The method for one-side polishing of a workpiece in accordance with one embodiment of the present disclosure can be performed, as one example, by using the polishing apparatus for a workpiece described above.

The method for one-side polishing of a workpiece W of this embodiment includes a polishing process for polishing one side of the workpiece W, using a polishing plate 2 with a larger diameter than the workpiece W; a polishing pad 3 attached to the polishing plate 2; a polishing head 4 that can hold the workpiece W and press the same against the polishing pad 3; and a polishing liquid supply nozzle 6 that supplies polishing liquid 5 to the polishing pad 3, and pressing the workpiece W against the polishing pad 3, while rotating the polishing plate 2 and the polishing pad 3 and supplying the polishing liquid 5 from the polishing liquid supply nozzle 6 to the polishing pad 3.

In the polishing process, one side of the workpiece W is polished while measuring displacement of the exposed upper surface 7 by a surface displacement measurement section 8 that can measure the displacement of the exposed upper surface 7.

According to the polishing method for a workpiece W in this embodiment, by continuously measuring the displacement of the exposed top surface 7 during one-side polishing of the workpiece W using the surface displacement measurement section 8, it is possible to understand the dynamic displacement behavior of the polishing pad, including the load and unloading of the pressing pressure from the workpiece W. By appropriately selecting the resolution of the surface displacement measurement section 8, for example, it is possible to grasp the temporal change in the displacement of the polishing pad 3 of several microns.

As described above, the method for one-side polishing of a workpiece W in this embodiment can measure the amount of dynamic displacement of the polishing pad during one-side polishing.

In the method for one-side polishing, it is preferable to polish one side of the workpiece W while removing the polishing liquid 5 from the exposed top surface 7. This is because it prevents the polishing liquid 5 from affecting the measurement, and allows accurately measuring the amount of dynamic displacement of the polishing pad 3 during one-side polishing. In the polishing process, it is preferable to polish one side of the workpiece W while blowing air 12 onto the exposed top surface 7 to remove the polishing liquid 5. This is because it allows avoiding the influences of polishing liquid 5 by a simple method.

In the method for one-side polishing, it is preferable to further include a preliminary process of measuring displacement of the exposed top surface 7 without pressing the workpiece W against the polishing pad 3, and to calculate a dynamic change in displacement of the exposed top surface 7 during one-side polishing of the workpiece W, by comparing a measurement result from the preliminary process with a result of measuring displacement of the exposed top surface 7 while pressing the workpiece W against the polishing pad 3. This is because it allows calculating the dynamic change in displacement of the exposed top surface 7 during one-side polishing of the workpiece W in absolute values (absolute quantity). In this preliminary process, the polishing head 4 is not in contact with the polishing pad 3, but is waiting above the polishing pad 3, so the pressure from the polishing head 4 is not transmitted to the polishing pad 3. However, the polishing liquid 5 is supplied, and at the measurement point for displacement, the measurement is performed while removing the polishing liquid 5 using the polishing liquid removal section 11.

### <Method for Manufacturing Silicon Wafers>

The method for manufacturing a polished workpiece in accordance with one embodiment of the present disclosure is to manufacture the polished workpiece by polishing one side of the workpiece W using the method for one-side polishing of a workpiece W described above. The workpiece used here is a silicon wafer.

According to the method for manufacturing a polished workpiece of this embodiment, it is possible to measure the amount of dynamic displacement of the polishing pad during one-side polishing.

Although not limited to, in the one-side polishing apparatus and the method for one-side polishing of a workpiece, a silicon wafer can be used as the workpiece.

When applied to the method for manufacturing silicon wafers, it can include the normal manufacturing process except for the one-side polishing. For example, after a single crystal is grown using the Czochralski method, it is sliced to make wafers, which are then processed through a series of processes such as lapping, etching, and double-side polishing. The one-side polishing described in this disclosure can then be applied to the wafers.

Examples of the present disclosure will be described below, but the present disclosure is not limited to the following examples in any way.

### EXAMPLES

In order to confirm the effectiveness of this disclosure, we used the one-side polishing apparatus as illustrated in FIGS. 1 and 2 to polish one side of five p-type silicon wafers with a diameter of 300 mm, and during the polishing process, we measured the dynamic change in displacement of the exposed top surface using a laser displacement meter while blowing air onto the exposed top surface. The laser displacement meter used was the IL-100 made by Keyence (measurement range: −2 mm to 2 mm, resolution: 2 μm, sampling time: 10 ms). The polishing head was set to apply 20 kPa of pressure to the wafer, and the polishing pad was set to rotate at 40 rpm.

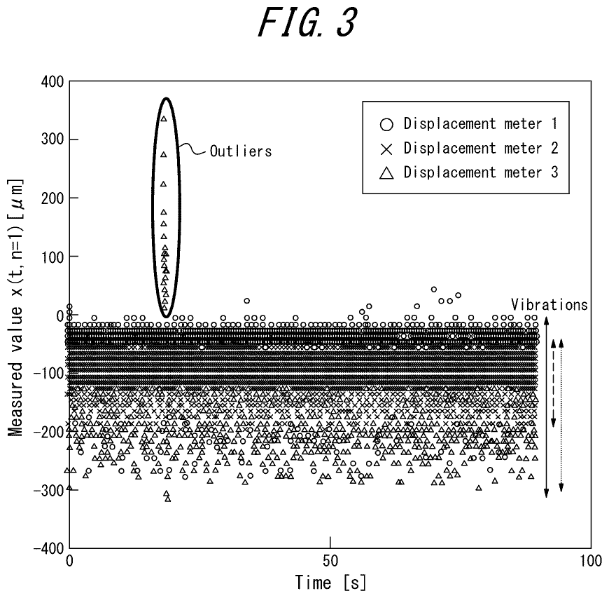

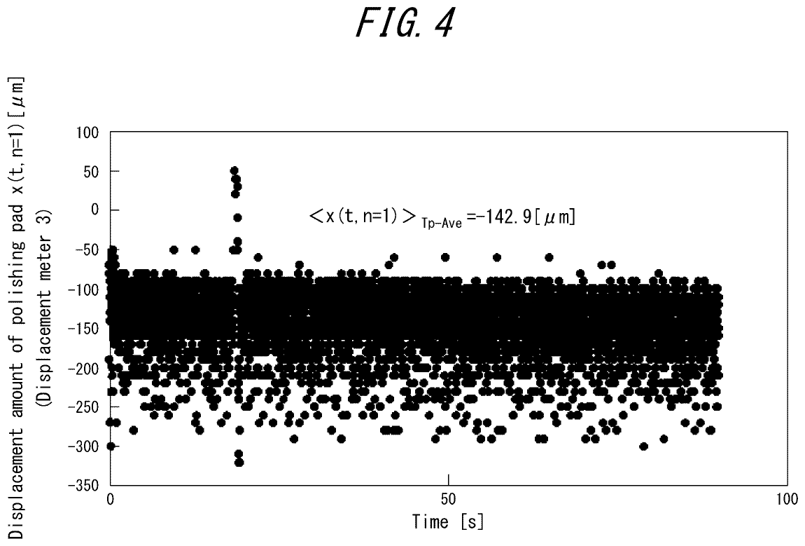

FIG. 3 is a graph that provides the relationship between measurement time and displacement of the exposed top surface. The displacement meters 1 to 3 in FIG. 3 correspond to the measurement points A to C, respectively. As can be seen in FIG. 3, there may be outliers in the data. Therefore, for the measurement data x(t,n) for each of the five sessions (number of samples N=5), values that were temporally discontinuous and differed greatly from other values (extremely outlying values) (we defined an extremely outlying value as one where |x(t,n)−<x(t,n)>_{Tp-Ave}|>200 μm) from the time average value <x(t,n)>_{Tp-Ave} were removed. The data after the removal of outliers is provided in FIG. 4. In FIG. 4, only the data from the displacement meter 3 is provided.

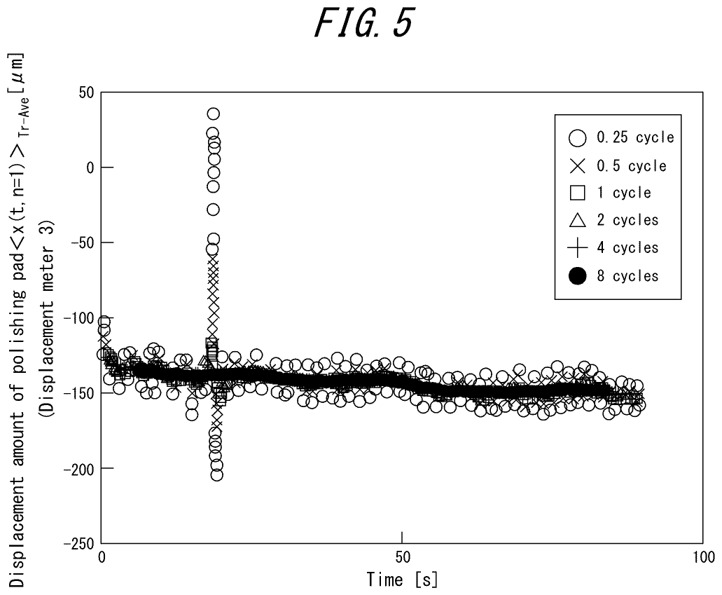

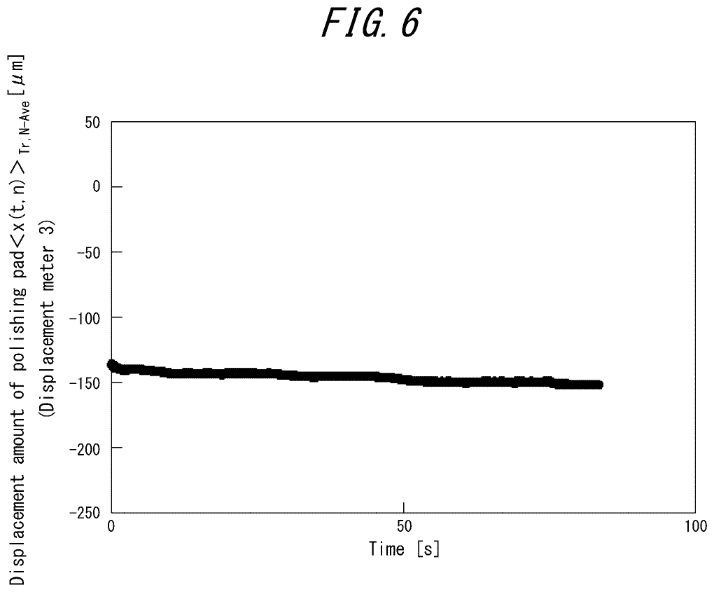

The data in FIG. 4 were subjected to a centered moving average (<x(t,n)>_{Tr-Ave}) in several times the rotation cycle Tr of the polishing head and the rotating plate. Any multiples may be used as long as it can eliminate vibrations and outliers, but if a large multiple is used, the centered moving average will result in significant loss of data on the start time side and the end time side of polishing. From this perspective, the following uses moving average data that is four times the rotation period Tr. FIG. 5 is a graph that provides data for the time moving average, in which the time width (several times the rotation cycle) for the centered moving average for the data in FIG. 4 is changed. FIG. 6 provides data in which the data in FIG. 4 are averaged by N, over N measurements and at each time t (<x(t,n)>_{Tr, N-Ave}).

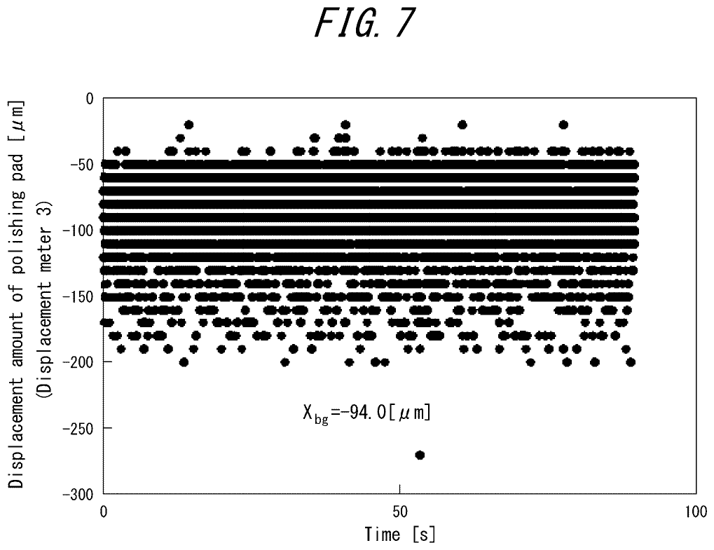

FIG. 7 is a graph that provides data from a preliminary process in which displacement of the exposed top surface is measured in the same way without pressing the wafer against the polishing pad. The reason why it is still vibrating (uneven) even in this state is that there is a thickness variation (which has been caused during manufacturing, attaching, and dressing) on the surface of the polishing pad. Here, the average value for the xbg data in FIG. 7 is subtracted from <x(t,n)>_{N, Tr-Ave} in FIG. 6 (take the difference).

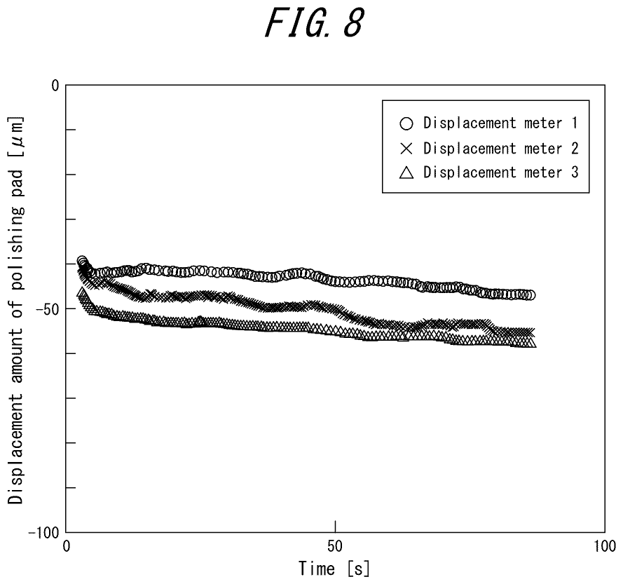

FIG. 8 is a graph that provides the relationship between the measurement time and the absolute amount of displacement of the exposed top surface, as calculated by taking the difference as above. Since the inclination of the laser displacement meter was set to 30°, the absolute amount of displacement of the polishing pad was calculated by multiplying cos 30° by <x(t,n)>_{N, Tr-Ave}-xbg. As provided in FIG. 8, it was revealed that the amount of displacement did not completely recover instantly between the polishing heads (displacement meters 1 to 3) which are due to the rotation of the polishing plate, and the amount of displacement remained, therefore it was possible to measure the amount of dynamic displacement of the polishing pad during one-side polishing.

As provided in FIG. 8, the absolute value of the displacement is increasing as the polishing time progresses, while the displacement value is negative. From this, it was revealed that the amount of displacement did not recover completely instantly even after the load from the wafer was removed, and that the amount of displacement accumulated due to repeated loading.

In this way, it was possible to measure the dynamic displacement of the polishing pad during one-side polishing.

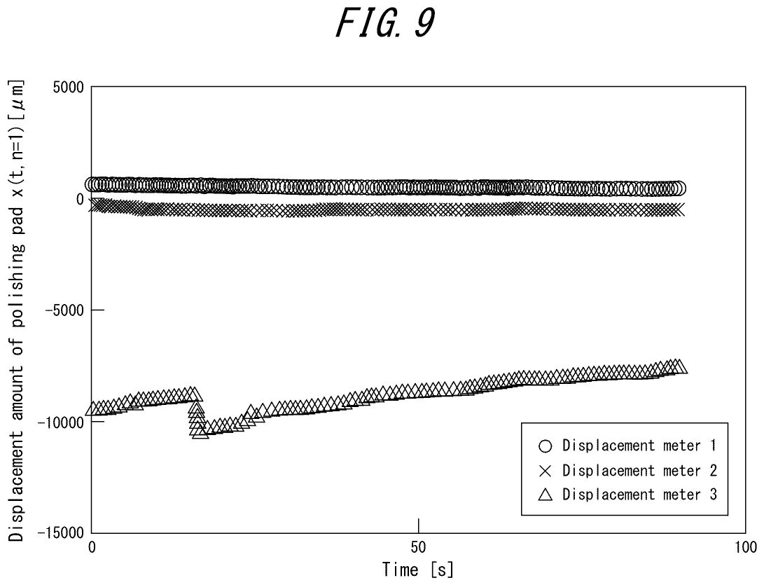

FIG. 9 provides the results of an experiment in which the air was not blown (the other conditions were the same). It can be seen that without air blowing, the amount of displacement of the polishing pad cannot be measured due to the influence of: the polishing head landing on the plate at the beginning of polishing, the inflow of slurry, and the existence of a slurry film during polishing (in this example, the data provides a positive value (tensile state with respect to the polishing pad)), therefore it was not possible to evaluate the viscoelastic properties of the polishing pad.

### REFERENCE SIGNS LIST

1 One-side polishing apparatus for workpiece
2 Polishing plate
3 Polishing pad
4 Polishing head
5 Polishing liquid
6 Polishing liquid supply nozzle
7 Exposed top surface
8 Surface displacement measurement section
9 Waterproof container
10 Draining slope
11 Polishing liquid removal section
12 Air

1. A one-side polishing apparatus for a workpiece, comprising:
a polishing plate with a larger diameter than the workpiece;
a polishing pad attached to the polishing plate;
a polishing head that can hold the workpiece and press the same against the polishing pad; and
a polishing liquid supply nozzle that supplies polishing liquid to the polishing pad, wherein
the apparatus further comprises a surface displacement measurement section that can measure displacement of an exposed top surface, which is a top surface of the polishing pad that is not covered by the polishing head.

2. The one-side polishing apparatus for a workpiece as described in claim 1, further comprising a polishing liquid removal section that removes the polishing liquid from the exposed top surface.

3. The one-side polishing apparatus for a workpiece as described in claim 2, wherein the polishing liquid removal section is configured to be capable of blowing air onto the exposed top surface.

4. The one-side polishing apparatus for a workpiece as described in claim 1, wherein the surface displacement measurement section is arranged at a plurality of the locations.

5. The one-side polishing apparatus for a workpiece as described in claim 1, wherein the workpiece is a wafer.

6. A method for one-side polishing of a workpiece, including: a polishing process for polishing one side of the workpiece,
using a polishing plate with a larger diameter than the workpiece; a polishing pad attached to the polishing plate; a polishing head that can hold the workpiece and press the same against the polishing pad; and a polishing liquid supply nozzle that supplies polishing liquid to the polishing pad, and
pressing the workpiece against the polishing pad while rotating the polishing plate and the polishing pad and supplying the polishing liquid from the polishing liquid supply nozzle to the polishing pad, wherein
in the polishing process, one side of the workpiece is polished while measuring displacement of an exposed upper surface, which is a top surface of the polishing pad that is not covered by the polishing head, by a surface displacement measurement section that can measure the displacement of the exposed upper surface.

7. The method for one-side polishing of a workpiece as described in claim 6, wherein one side of the workpiece is polished while removing the polishing liquid from the exposed top surface.

8. The method for one-side polishing of a workpiece as described in claim 7, wherein in the polishing process, one side of the workpiece is polished while blowing air onto the exposed top surface to remove the polishing liquid.

9. The method for one-side polishing of a workpiece as described in claim 6, further including a preliminary process for measuring displacement of the exposed top surface without pressing the workpiece against the polishing pad, wherein
a dynamic change in displacement of the exposed top surface during one-side polishing of the workpiece is calculated by comparing a measurement result from the preliminary process with a result of measuring the displacement of the exposed top surface while pressing the workpiece against the polishing pad.

10. The method for one-side polishing of a workpiece as described in claim 6, wherein the workpiece is a wafer.

11. A method for manufacturing silicon wafers using the method for one-side polishing of a workpiece as described in claim 10.
